(19) United States
(12) Patent Application Publication
(10) Pub. No.: US 2024/0087848 A1
(43) Pub. Date: Mar. 14, 2024

(54) PULSED VOLTAGE SOURCE FOR PLASMA PROCESSING APPLICATIONS

(71) Applicant: Applied Materials, Inc., Santa Clara, CA (US)

(72) Inventors: Fabrice CUBAYNES, Saint-Jean-Lagineste (FR); Dmitry GRISHIN, Saint Cere (FR)

(21) Appl. No.: 18/507,260

(22) Filed: Nov. 13, 2023

Related U.S. Application Data
(63) Continuation of application No. 17/961,452, filed on Oct. 6, 2022.
Application No. 17/961,452 is a continuation of application No. 17/356,446, filed on Jun. 23, 2021, now Pat. No. 11,569,066.

(51) Int. Cl. H01J 37/32; H03K 17/687

(52) U.S. Cl. CPC H01J 37/32128; H03K 17/6871; H02M 3/24

(57) ABSTRACT

Embodiments provided herein generally include apparatus, e.g., plasma processing systems, and methods for the plasma processing of a substrate in a processing chamber. Some embodiments are directed to a waveform generator. The waveform generator generally includes a first voltage stage having: a first voltage source; a first switch; and a second switch, where a first terminal of the first voltage source is coupled to a first terminal of the first switch, and where a second terminal of the first voltage source is coupled to a first terminal of the second switch. The waveform generator also includes a current stage coupled to a common node between second terminals of the first switch and the second switch, the current stage having a current source and a third switch coupled to the current source.

### CROSS REFERENCE TO RELATED APPLICATIONS

This application is a continuation of U.S. patent application Ser. No. 17/961,452, filed Oct. 6, 2022, which is a continuation of U.S. patent application Ser. No. 17/356,446, filed Jun. 23, 2021, both of which are expressly incorporated herein by reference in their entireties.

### BACKGROUND

### Field

Embodiments of the present disclosure generally relate to a system used in semiconductor device manufacturing. More specifically, embodiments of the present disclosure relate to a plasma processing system used to process a substrate.

### Description of the Related Art

Reliably producing high aspect ratio features is one of the key technology challenges for the next generation of semiconductor devices. One method of forming high aspect ratio features uses a plasma-assisted etching process to bombard a material formed on a surface of a substrate through openings formed in a patterned mask layer formed on the substrate surface.

With technology node advancing towards 2 nm, the fabrication of smaller features with larger aspect ratios requires atomic precision for plasma processing. For etching processes where the plasma ions play a major role, ion energy control is always challenging the semiconductor equipment industry. In a typical plasma-assisted etching process, the substrate is positioned on an electrostatic chuck (ESC) disposed in a processing chamber, a plasma is formed over the substrate, and ions are accelerated from the plasma towards the substrate across a plasma sheath, i.e., region depleted of electrons, formed between the plasma and the surface of the substrate. Traditionally RF substrate biasing methods, which use sinusoidal RF waveforms to excite the plasma and form the plasma sheath, have been unable to desirably form these smaller device feature sizes. Recently, it has been found that the delivery of high voltage DC pulses to one or more electrodes within a processing chamber can be useful in desirably controlling the plasma sheath formed over the surface of the substrate.

However, producing high voltage pulses with fast rise times and/or fast fall times is challenging. For instance, to achieve a fast rise time and/or a fast fall time (e.g., <2.5 μs) for a high voltage pulse (e.g., >5 kV), the slope of the pulse rise and/or fall must be very steep (e.g., >10 V/s). Such steep rise times and/or fall times are very difficult to produce especially in circuits driving a load with a low capacitance. Such pulse may be especially difficult to produce using standard electrical components in a compact manner; and/or with pulses having variable pulse widths, voltages, and repetition rates; and/or within applications having capacitive loads such as, for example, forming a plasma.

Accordingly, there is a need in the art for pulsed voltage source and biasing methods that are able to enable the completion of a desirable plasma-assisted process on a substrate.

### SUMMARY

Embodiments provided herein generally include apparatus, e.g., plasma processing systems, and methods for the plasma processing of a substrate in a processing chamber.

Some embodiments are directed to a waveform generator. The waveform generator generally includes a first voltage stage having: a first voltage source; a first switch; and a second switch, wherein a first terminal of the first voltage source is coupled to a first terminal of the first switch, and wherein a second terminal of the first voltage source is coupled to a first terminal of the second switch. The waveform generator also includes a current stage coupled to a common node between second terminals of the first switch and the second switch, the current stage having a current source and a third switch coupled to the current source.

Some embodiments are directed to a method for waveform generation. The method generally includes incorporating, during a first mode of operation, a first voltage source in an output current path of a waveform generator by controlling multiple switches, and incorporating, during a second mode of operation, a current source in the output current path by controlling the multiple switches. The multiple switches include: a first switch; a second switch, wherein a first terminal of the first voltage source is coupled to a first terminal of the first switch, and wherein a second terminal of the first voltage source is coupled to a first terminal of the second switch; and a third switch coupled in parallel with the current source, the third switch being coupled to a common node between second terminals of the first switch and the second switch.

Some embodiments are directed to an apparatus for waveform generation. The apparatus generally includes a memory, and one or more processors coupled to the memory. The memory and the one or more processors may be configured to: incorporate, during a first mode of operation, a first voltage source in an output current path of a waveform generator by controlling multiple switches; and incorporate, during a second mode of operation, a current source in the output current path by controlling the multiple switches. The multiple switches include: a first switch; a second switch, wherein a first terminal of the first voltage source is coupled to a first terminal of the first switch, and wherein a second terminal of the first voltage source is coupled to a first terminal of the second switch; and a third switch coupled in parallel with the current source, the third switch being coupled to a common node between second terminals of the first switch and the second switch.

### BRIEF DESCRIPTION OF THE DRAWINGS

So that the manner in which the above -recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIG. 1 is a schematic cross-sectional view of a processing system, according to one or more embodiments, configured to practice the methods set forth herein.

FIG. 2 illustrates stray capacitance and substrate support capacitance associated with a processing chamber.

FIGS. 3A 3B, and 3C show example voltage waveforms for plasma processing.

FIG. 4 illustrates a pulser, in accordance with certain embodiments of the present disclosure.

FIG. 5A illustrates various modes of operation of a pulser, in accordance with certain embodiments of the present disclosure.

FIG. 5B is a timing diagram showing states of switches of the pulser during various modes of operation, in accordance with certain embodiments of the present disclosure.

FIG. 6 illustrates a charging circuit used to charge a capacitive element, in accordance with certain aspects of the present disclosure.

FIG. 7 is a process flow diagram illustrating a method of waveform generation, in accordance with certain embodiments of the present disclosure.

### DETAILED DESCRIPTION

Certain aspects of the present disclosure are generally directed to techniques for generating a voltage waveform for a plasma processing system. During the plasma processing of a substrate the voltage waveform, which is provided to an electrode disposed within a plasma processing chamber, will typically be configured to include a sheath collapse stage and an ion current stage. The sheath collapse stage may be implemented by generating a positive voltage (e.g., 100 volts) to be used to collapse a sheath generated over a surface of the substrate disposed on a substrate support positioned in a processing chamber. During the ion current stage, ions within the processing chamber may begin to flow by generating a negative voltage (e.g., −1600 volts). In some embodiments, a voltage during the ion current stage of the waveform may have a ramp to implement current compensation, as described in more detail herein. The voltage waveform may be generated by selectively incorporating various voltage sources (e.g., capacitive element) in an output current path of a waveform generator.

### Plasma Processing System Examples

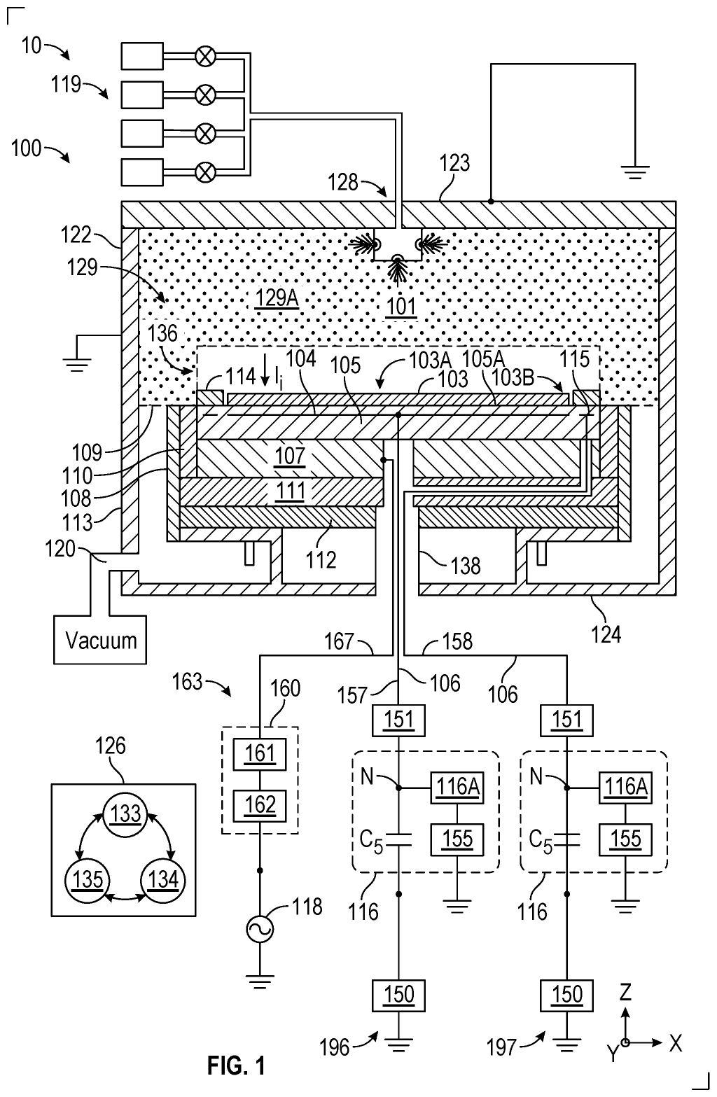

FIG. 1 is a schematic cross-sectional view of a processing system 10 configured to perform one or more of the plasma processing methods set forth herein. In some embodiments, the processing systems 10 is configured for plasma-assisted etching processes, such as a reactive ion etch (RIE) plasma processing. However, it should be noted that the embodiments described herein may be also be used with processing systems configured for use in other plasma-assisted processes, such as plasma-enhanced deposition processes, for example, plasma-enhanced chemical vapor deposition (PECVD) processes, plasma-enhanced physical vapor deposition (PEPVD) processes, plasma-enhanced atomic layer deposition (PEALD) processes, plasma treatment processing or plasma-based ion implant processing, for example, plasma doping (PLAD) processing.

As shown, the processing system 10 is configured to form a capacitively coupled plasma (CCP), where the processing chamber 100 includes an upper electrode (e.g., chamber lid 123) disposed in a processing volume 129 facing a lower electrode (e.g., the substrate support assembly 136) also disposed in the processing volume 129. In a typical capacitively coupled plasma (CCP) processing system, a radio frequency (RF) source (e.g., RF generator 118) is electrically coupled to one of the upper or lower electrode, and delivers an RF signal configured to ignite and maintain a plasma (e.g., the plasma 101). In this configuration, the plasma is capacitively coupled to each of the upper and lower electrodes and is disposed in a processing region therebetween. Typically, the opposing one of the upper or lower electrodes is coupled to ground or to a second RF power source. One or more components of the substrate support assembly 136, such as the support base 107 is electrically coupled to a plasma generator assembly 163, which includes the RF generator 118, and the chamber lid 123 is electrically coupled to ground. As shown, the processing system 10 includes a processing chamber 100, a support assembly 136, and a system controller 126.

The processing chamber 100 typically includes a chamber body 113 that includes the chamber lid 123, one or more sidewalls 122, and a chamber base 124, which collectively define the processing volume 129. The one or more sidewalls 122 and chamber base 124 generally include materials that are sized and shaped to form the structural support for the elements of the processing chamber 100 and are configured to withstand the pressures and added energy applied to them while a plasma 101 is generated within a vacuum environment maintained in the processing volume 129 of the processing chamber 100 during processing. In one example, the one or more sidewalls 122 and chamber base 124 are formed from a metal, such as aluminum, an aluminum alloy, or a stainless steel alloy.

A gas inlet 128 disposed through the chamber lid 123 is used to deliver one or more processing gases to the processing volume 129 from a processing gas source 119 that is in fluid communication therewith. A substrate 103 is loaded into, and removed from, the processing volume 129 through an opening (not shown) in one of the one or more sidewalls 122, which is sealed with a slit valve (not shown) during plasma processing of the substrate 103.

The system controller 126, also referred to herein as a processing chamber controller, includes a central processing unit (CPU) 133, a memory 134, and support circuits 135. The system controller 126 is used to control the process sequence used to process the substrate 103, including the substrate biasing methods described herein. The CPU 133 is a general-purpose computer processor configured for use in an industrial setting for controlling the processing chamber and sub-processors related thereto. The memory 134 described herein, which is generally non-volatile memory, may include random access memory, read-only memory, floppy or hard disk drive, or other suitable forms of digital storage, local or remote. The support circuits 135 are conventionally coupled to the CPU 133 and comprise cache, clock circuits, input/output subsystems, power supplies, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the processing system 10.

Typically, the program, which is readable by CPU 133 in the system controller 126, includes code, which, when executed by the processor (CPU 133), performs tasks relating to the plasma processing schemes described herein. The program may include instructions that are used to control the various hardware and electrical components within the processing system 10 to perform the various process tasks and various process sequences used to implement the methods described herein. In one embodiment, the program includes instructions that are used to perform one or more of the operations described below in relation to FIG. 7.

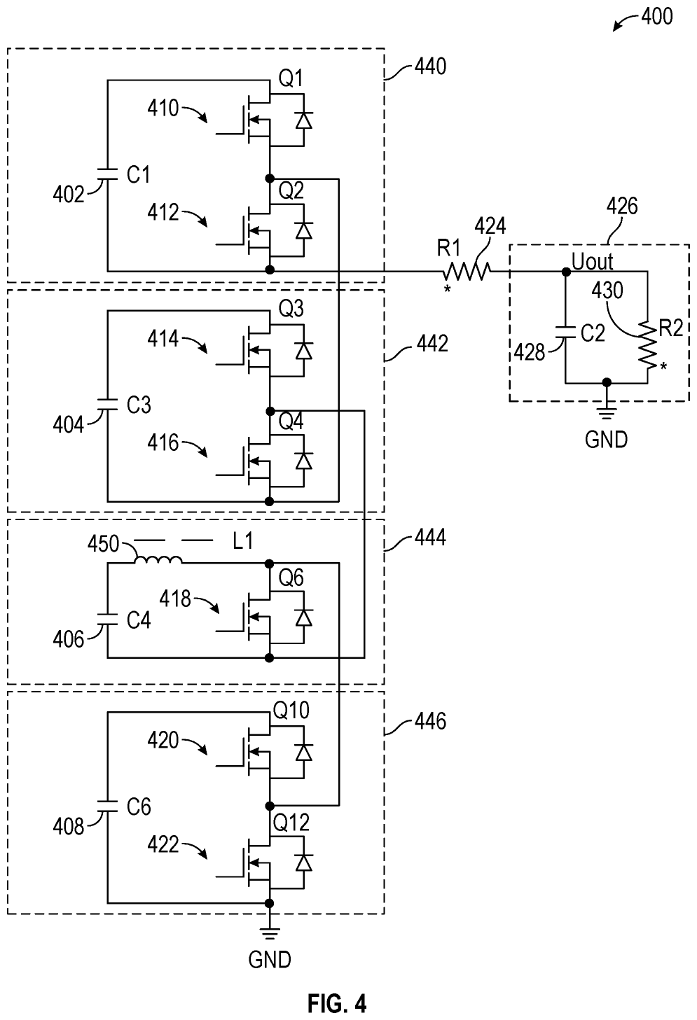

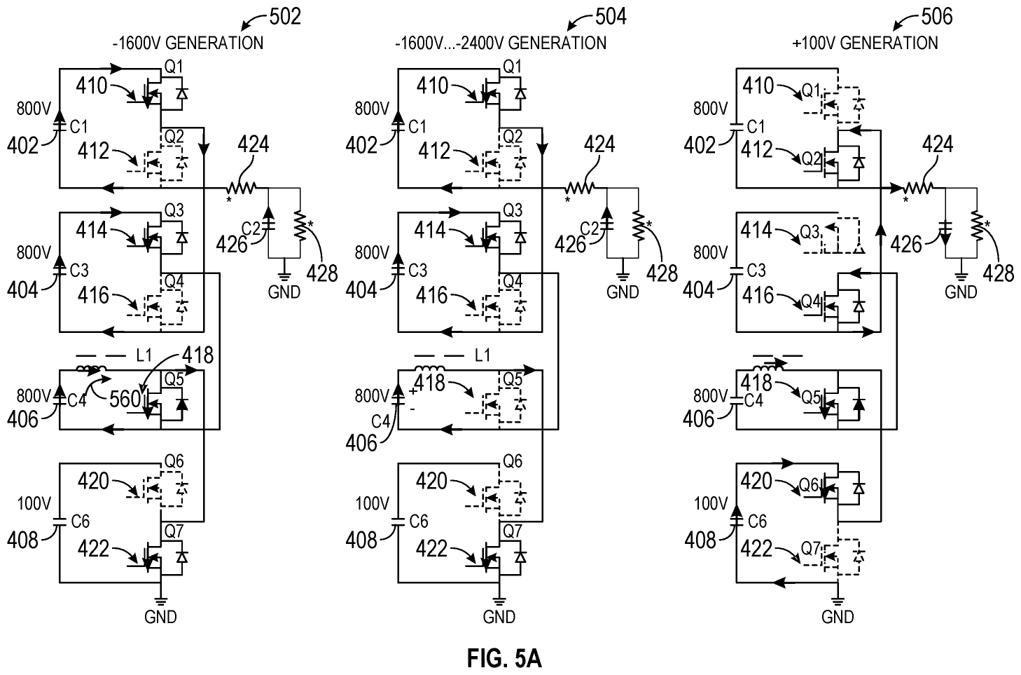

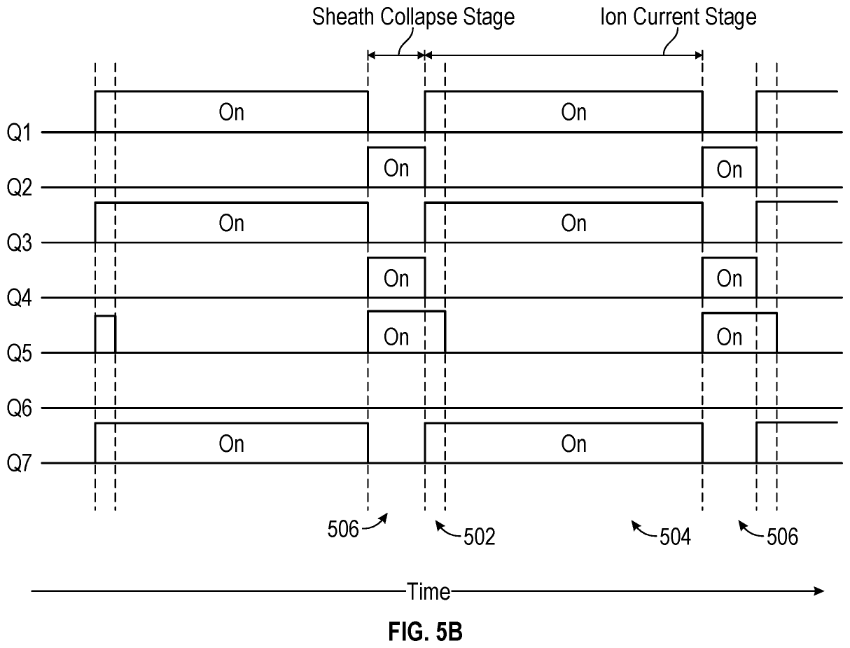

The processing system may include a plasma generator assembly 163, a first pulsed voltage (PV) source assembly 196 For establishing a first PV waveform at a bias electrode 104, and a second PV source assembly 197 for establishing a second PV waveform at an edge control electrode 115. The first PV waveform or the second PV waveform may be generated using a waveform generator as described in more detail herein with respect to FIGS. 4, 5A, and 5B. In some embodiments, the plasma generator assembly 163 delivers an RF signal to the support base 107 (e.g., power electrode or cathode) which may be used to generate (maintain and/or ignite) a plasma 101 in a processing region disposed between the substrate support assembly 136 and the chamber lid 123. In some embodiments, the RF generator 118 is configured to deliver an RF signal having a frequency that is greater than 1 MHz or more, or about 2 MHz or more, such as about 13.56 MHz or more.

As discussed above, in some embodiments, the plasma generator assembly 163, which includes an RF generator 118 and an RF generator assembly 160, is generally configured to deliver a desired amount of a continuous wave (CW) or pulsed RF power at a desired substantially fixed sinusoidal waveform frequency to a support base 107 of the substrate support assembly 136 based on control signals provided from the system controller 126. During processing, the plasma generator assembly 163 is configured to deliver RF power (e.g., an RF signal) to the support base 107 disposed proximate to the substrate support 105, and within the substrate support assembly 136. The RF power delivered to the support base 107 is configured to ignite and maintain a processing plasma 101 of processing gases disposed within the processing volume 129.

In some embodiments, the support base 107 is an RF electrode that is electrically coupled to the RF generator 118 via an RF matching circuit 162 and a first filter assembly 161, which are both disposed within the RF generator assembly 160. The first filter assembly 161 includes one or more electrical elements that are configured to substantially prevent a current generated by the output of a PV waveform generator 150 from flowing through an RF power delivery line 167 and damaging the RF generator 118. The first filter assembly 161 acts as a high impedance (e.g., high Z) to the PV signal generated from a PV pulse generator P1 within the PV waveform generator 150, and thus inhibits the flow of current to the RF matching circuit 162 and RF generator 118.

In some embodiments, the RF generator assembly 160 and RF generator 118 are used to ignite and maintain a processing plasma 101 using the processing gases disposed in the processing volume 129 and fields generated by the RF power (RF signal) delivered to the support base 107 by the RF generator 118. The processing volume 129 is fluidly coupled to one or more dedicated vacuum pumps through a vacuum outlet 120, which maintain the processing volume 129 at sub-atmospheric pressure conditions and evacuate processing and/or other gases, therefrom. In some embodiments, the substrate support assembly 136, disposed in the processing volume 129, is disposed on a support shaft 138 that is grounded and extends through the chamber base 124. However, in some embodiments, the RF generator assembly 160 is configured to deliver an RF power to the bias electrode 104 disposed in the substrate support 105 versus the support base 107.

The substrate support assembly 136, as briefly discussed above, generally includes the substrate support 105 (e.g., ESC substrate support) and support base 107. In some embodiments, the substrate support assembly 136 can additionally include an insulator plate 111 and a ground plate 112, as is discussed further below. The support base 107 is electrically isolated from the chamber base 124 by the insulator plate 111, and the ground plate 112 is interposed between the insulator plate 111 and the chamber base 124. The substrate support 105 is thermally coupled to and disposed on the support base 107. In some embodiments, the support base 107 is configured to regulate the temperature of the substrate support 105, and the substrate 103 disposed on the substrate support 105, during substrate processing.

Typically, the substrate support 105 is formed of a dielectric material, such as a bulk sintered ceramic material, such as a corrosion-resistant metal oxide or metal nitride material, for example, aluminum oxide (Al₂O₃), aluminum nitride (AlN), titanium oxide (TiO), titanium nitride (TiN), yttrium oxide (Y₂O₃), mixtures thereof, or combinations thereof. In embodiments herein, the substrate support 105 further includes the bias electrode 104 embedded in the dielectric material thereof. In some embodiments, one or more characteristics of the RF power used to maintain the plasma 101 in the processing region over the bias electrode 104 are determined and/or monitored by measuring an RF waveform established at the bias electrode 104.

In one configuration, the bias electrode 104 is a chucking pole used to secure (i.e., chuck) the substrate 103 to the substrate supporting surface 105A of the substrate support 105 and to bias the substrate 103 with respect to the processing plasma 101 using one or more of the pulsed-voltage biasing schemes described herein. Typically, the bias electrode 104 is formed of one or more electrically conductive parts, such as one or more metal meshes, foils, plates, or combinations thereof.

In some embodiments, the bias electrode 104 is electrically coupled to a clamping network 116, which provides a chucking voltage thereto, such as static DC voltage between about −5000 V and about 5000 V, using an electrical conductor, such as the coaxial power delivery line 106 (e.g., a coaxial cable). As will be discussed further below, the clamping network 116 includes bias compensation circuit elements 116A, a DC power supply 155, and a bias compensation module blocking capacitor, which is also referred to herein as the blocking capacitor C₅. The blocking capacitor C₅ is disposed between the output of a pulsed voltage (PV) waveform generator 150 and the bias electrode 104.

The substrate support assembly 136 may further include the edge control electrode 115 that is positioned below the edge ring 114 and surrounds the bias electrode 104 and/or is disposed a distance from a center of the bias electrode 104. In general, for a processing chamber 100 that is configured to process circular substrates, the edge control electrode 115 is annular in shape, is made from a conductive material, and is configured to surround at least a portion of the bias electrode 104. In some embodiments, such as shown in FIG. 1, the edge control electrode 115 is positioned within a region of the substrate support 105. In some embodiments, as illustrated in FIG. 1, the edge control electrode 115 includes a conductive mesh, foil, and/or plate that is disposed a similar distance (i.e., Z-direction) from the substrate supporting surface 105A of the substrate support 105 as the bias electrode 104. In some other embodiments, the edge control electrode 115 includes a conductive mesh, foil, and/or plate that is positioned on or within a region of a quartz pipe 110, which surrounds at least a portion of the bias electrode 104 and/or the substrate support 105. Alternately, in some other embodiments (not shown), the edge control electrode 115 is positioned within or is coupled to the edge ring 114, which is disposed on and adjacent to the substrate support 105. In this configuration, the edge ring 114 is formed from a semiconductor or dielectric material (e.g., AlN, etc.).

The edge control electrode 115 can be biased by use of a PV waveform generator that is different from the PV waveform generator 150 that is used to bias the bias electrode 104. In some embodiments, the edge control electrode 115 can be biased by use of a PV waveform generator 150 that is also used to bias the bias electrode 104 by splitting part of the power to the edge control electrode 115. In one configuration, a first PV waveform generator 150 of the first PV source assembly 196 is configured to bias the bias electrode 104, and a second PV waveform generator 150 of a second PV source assembly 197 is configured to bias the edge control electrode 115.

A power delivery line 157 electrically connects the output of the PV waveform generator 150 of the first PV source assembly 196 to an optional filter assembly 151 and the bias electrode 104. While the discussion below primarily discusses the power delivery line 157 of the first PV source assembly 196, which is used to couple a PV waveform generator 150 to the bias electrode 104, the power delivery line 158 of the second PV source assembly 197, which couples a PV waveform generator 150 to the edge control electrode 115, will include the same or similar components. The electrical conductor(s) within the various parts of the power delivery line 157 may include: (a) one or a combination of coaxial cables, such as a flexible coaxial cable that is connected in series with a rigid coaxial cable, (b) an insulated high-voltage corona-resistant hookup wire, (c) a bare wire, (d) a metal rod, (e) an electrical connector, or (f) any combination of electrical elements in (a)-(e). The optional filter assembly 151 includes one or more electrical elements that are configured to substantially prevent a current generated by the output of the RF generator 118 from flowing through the power delivery line 157 and damaging the PV waveform generator 150. The optional filter assembly 151 acts as a high impedance (e.g., high Z) to RF signal generated by the RF generator 118, and thus inhibits the flow of current to the PV waveform generator 150.

The second PV source assembly 197 includes a clamping network 116 so that a bias applied to the edge control electrode 115 can be similarly configured to the bias applied to the bias electrode 104 by the clamping network 116 coupled within the first PV source assembly 196. Applying similarly configured PV waveforms and clamping voltages to the bias electrode 104 and edge control electrode 115 can help improve the plasma uniformity across the surface of the substrate during processing and thus improve the plasma processing process results.

In some embodiments, the processing chamber 100 further includes the quartz pipe 110, or collar, that at least partially circumscribes portions of the substrate support assembly 136 to prevent the substrate support 105 and/or the support base 107 from contact with corrosive processing gases or plasma, cleaning gases or plasma, or byproducts thereof. Typically, the quartz pipe 110, the insulator plate 111, and the ground plate 112 are circumscribed by a liner 108. In some embodiments, a plasma screen 109 is positioned between the cathode liner 108 and the sidewalls 122 to prevent plasma from forming in a volume underneath the plasma screen 109 between the liner 108 and the one or more sidewalls 122.

### Example Representative Circuit of a Processing Chamber

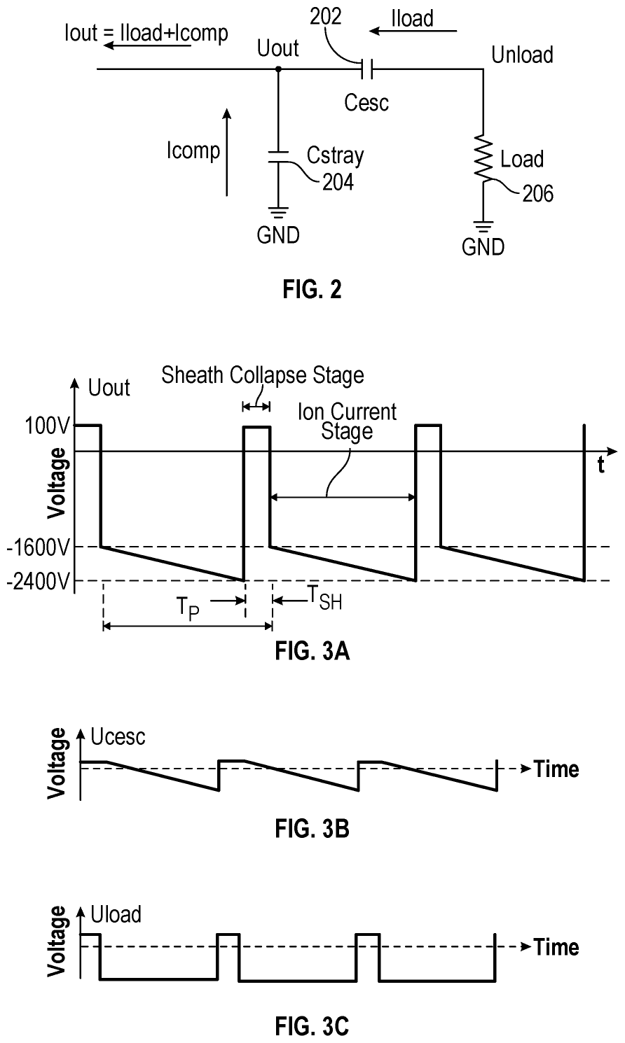

FIG. 2 illustrates stray capacitance and escape capacitance associated with a processing chamber. The stray capacitance 204 (C_{stray}) represents the capacitance between an electrode of the processing chamber and ground, and a substrate support capacitance 202, also referred to herein as an electrostatic chuck capacitance (C_{esc}), which represents the capacitance between the bias electrode 104 and the substrate supporting surface 105A. As shown, C_{esc} is coupled between an output node (labeled Uₒᵤₜ) and a load represented by resistive element 206. To have a square shape for a voltage pulse on the load (e.g., at node U_{load}), a slope is implemented for the voltage across C_{esc} and the voltage across C_{stray} (e.g., voltage at Uₒᵤₜ), as described in more detail herein. The current across C_{stray} (e.g., compensation current (I_{comp})) may be equal to the load current (I_{load}) across C_{esc} multiplied by the ratio of the capacitance of C_{stray} and the capacitance of C_{esc}. The output current (Iₒᵤₜ) may be equal to the sum of I_{load} and Icomp, which may be represented by the equation:

$$Iout = Iload ( 1 + \frac{C s t r a y}{C e s c} )$$

### Example Voltage Waveform for Processing Chamber

FIG. 3A shows a voltage waveform that may be established at an electrode disposed within a processing chamber, such as the electrode 104 shown in FIG. 1. The waveform includes two stages, an ion current stage and a sheath collapse stage. At the beginning of the ion current stage, a drop of wafer voltage creates a high voltage sheath above the substrate, accelerating positive ions to the substrate 103. The positive ions deposit a positive charge on the substrate surface and tend to gradually increase the substrate voltage positively. If a square wave is supplied, the ion current towards the substrate creates a positive slope of the substrate voltage (e.g., at U_{load} shown in FIG. 2). To have a square shape for the voltage pulse on the load (e.g., at U_{load}) as shown in FIG. 3C, a slope is implemented for the voltage at Uₒᵤₜ during the ion current stage, as shown in FIG. 3A, is used to form the voltage across the electrostatic chuck capacitive element C_{esc}, as shown in FIG. 3B. Implementing the slope at the electrode 104 and electrostatic chuck capacitor C_{esc} during the ion current stage is generally referred to as current compensation, which is used to form the constant voltage seen at U_{load} during this stage. The voltage difference between the beginning and end of the ion current phase determines the ion energy distribution function (IEDF) width. The larger the voltage difference, the wider the distribution of ion energies, and thus a wider IEDF width. To achieve monoenergetic ions and a narrower IEDF width, current compensation operations are performed to flatten the substrate voltage waveform in the ion current phase. In some embodiments, the voltage waveforms can be delivered at a frequency (1/Tₚ) between about 50 kHz and 1000 kHz. In some embodiments, voltage waveform established at the electrode has an on-time, which is defined as the ratio of the ion current time period (e.g., length of ion current stage) and the waveform period T_{P} (e.g., length of sheath collapse stage+length of ion current stage), is greater than 50%, or greater than 70%, such as between 80% and 95%. In some embodiments, a voltage waveform, which has a waveform cycle has a period T_{P} (e.g., about 2.5 μs), is serially repeated within a waveform burst that has a burst period that is between about 100 microseconds (μs) and about 10 milliseconds (ms). The burst of PV waveforms can have a burst duty cycle that is between about 5%-100%, such as between about 50% and about 95%, wherein the duty cycle is the ratio of the burst period divided by the burst period plus a non-burst period (i.e., no PV waveforms are generated) that separates the burst periods. As shown, the sheath collapse stage may have a duration of T_{SH}, which may be about 200 ns.

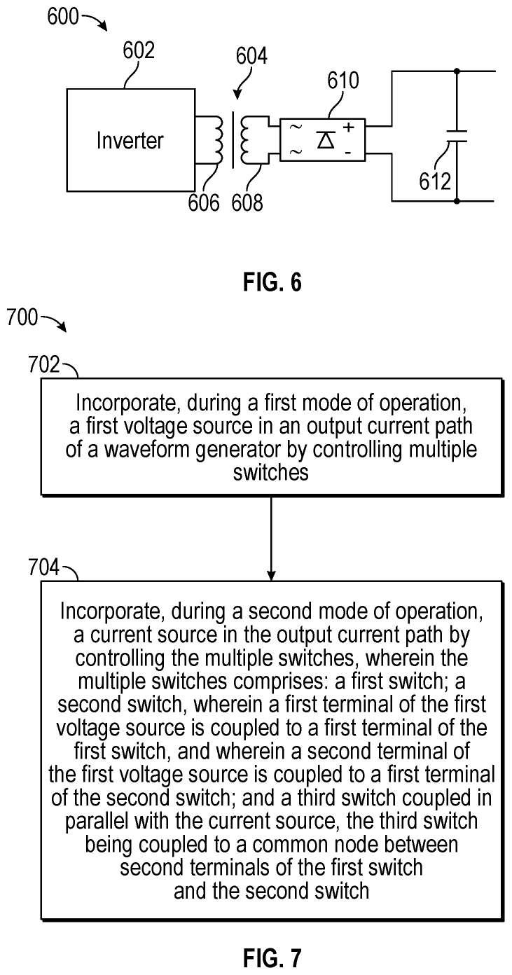

FIG. 4 illustrates a pulser 400 (also referred to herein as a waveform generator), in accordance with certain embodiments of the present disclosure. As shown, the pulser 400 may include pulse capacitive elements 402, 404, 406, and 408 (labeled C1, C3, C4, and C6), as well as transistors 410, 412, 414, 416, 418, 420, 422 (labeled as transistors Q1, Q2, Q3, Q4, Q6, Q10, and Q12). Transistors 410, 412, 414, 416, 418, 420, 422 (also referred to herein as switches) may be power transistors (e.g., metal-oxide-semiconductor field-effect transistors (MOSFETs)) with a parallel diode (e.g., a body diode). Transistors 410, 412, 414, 416, 418, 420, 422 may be used to select a current flow path (also referred to as an output current path) for the pulser as described in more detail herein. Capacitive elements 402, 404, 406, and 408 may serve as voltage storage elements that may be charged using a charging circuit, such as the circuit illustrated in FIG. 6. The capacitive elements illustrated in FIGS. 4, 5A and 6, are in effect acting as voltage sources. While the example pulser 400 illustrates capacitive elements to facilitate understanding, any suitable voltage source may be used.

The resistive element 424 (labeled R1) represents an internal serial resistive element of the pulser coupled to the load 426. The load 426, which may be a plasma formed in plasma processing chamber, may be represented by capacitive element 428 (labeled C2) and resistive element 430 (labeled R2). As shown, the capacitive element 402 and transistors 410, 412 form a first voltage stage 440, and the capacitive element 404 and transistors 414, 416 for a second voltage stage 442. The pulser 400 also includes a current stage 444 having the capacitive element 406, the transistor 418, and an inductive element 450, as well as a third voltage stage 446 having the capacitive element 408 and transistors 420, 422. While the pulser 400 is implemented with three voltage stages, the aspects of the present disclosure may be implemented with one, two, or more than three voltage stages. In some embodiments of a pulser 400, one or more of the voltage stages may be duplicated one or more times, such as a configuration that includes a first voltage stage 440, two or more second voltage stages 442, a current stage 444, and a third voltage stage 446, wherein the two or more second voltage stages 442 are connected in series between the first voltage stage 440 and the current stage 444.

As shown, each of the capacitive elements 402, 404, 406, and 408 may be charged to a specific voltage, depending on the waveform being implemented. For example, each of the capacitive elements 402, 404, 406 are charged to 800 volts, and capacitive element 408 is charged to 100 volts. In some implementations, the capacitive elements 402, 404, 406, 408 may be charged to greater or lower voltages to implement different voltages levels for a waveform suitable for different implementations. In some embodiments, each of the voltage stages 440, 442, 446 and current stage 444 may have a modular design that facilitates easy replacement in case of malfunction. The operation of the pulser 400 for generating the waveform shown in FIG. 3A is described in more detail with respect to FIG. 5.

FIG. 5A illustrates various modes of operation of the pulser 400, in accordance with certain embodiments of the present disclosure. The magnitudes of the voltages associated with the various modes of operation 502, 504, 506 and circuit elements illustrated in FIG. 5A are intended to provide examples of voltages that may be established during the generation of a pulsed waveform and are not intended to be limiting as to the scope of the disclosure provided herein. FIG. 5B is a timing diagram showing a state of each of transistors 410, 412, 414, 416, 418, 420, 422 (e.g., transistors Q1, Q2, Q3, Q4, Q6, Q10, and Q12). During the sheath collapse stage, the voltage at Uₒᵤₜ may be set to 100 volts, as an example. To transition from the sheath collapse stage to the ion current stage, transistors Q1, Q3, Q5, and Q7 may be turned on and transistors Q2, Q4, Q6 may be turned off to implement a voltage drop from 100 volts to −1600 volts, as shown by mode of operation 502. Turning on transistors Q1, Q3, Q5, and Q7 and turning off transistors Q2, Q4, Q6 effectively incorporates the capacitive elements 402, 404 in the output current path of the pulser, as shown. In the mode of operation 502, Iₒᵤₜ flows from ground through capacitive elements C2, C1, transistor Q1, capacitive element C3, and transistors Q3, Q5, and Q7. The capacitive elements C1 and C3 set the voltage at Uₒᵤₜ to −1600 volts (e.g., −800 volts from capacitive element C1 and −800 volts from capacitive element C3). While two voltage stages are used to implement the −1600 volts during the ion current stage, each voltage stage providing −800 volts, a single voltage stage may be used. For example, the capacitive element of the single voltage stage may be charged to 1600 volts to provide the −1600 volts at Uₒᵤₜ during the ion current stage. As shown, during the mode of operation 502, Iₒᵤₜ flows across the parallel diode (e.g., body diode) of transistor Q5, and flows across transistor Q7 back to ground. With transistor Q5 being turned on, current 560 flows in a loop through capacitive element C4, inductive element L1, and from the drain to source of transistor Q5.

Once the voltage at Uₒᵤₜ reaches −1600 volts, the mode of operation 504 may be implemented. During mode of operation 504, a current source, implemented using capacitive element C4 and inductive element L1, may be incorporated in the output current path of the pulser 400. As shown, transistor Q5 may be turned off, and Iₒᵤₜ will begin to flow across capacitive element C4 and inductive element L1 (e.g., instead of through the parallel diode of transistor Q5 during mode of operation 502). Capacitive element C4 and inductive element L1 implement a current source, effectively gradually decreasing the voltage at Uₒᵤₜ to implement the slope during the ion current stage for ion current compensation, as described with respect to FIG. 3A. For example, during the ion current stage, the voltage at Uₒᵤₜ may decrease from −1600 volts to −2400 volts.

Once the voltage at Uₒᵤₜ has reached −2400 voltages, the mode of operation 506 may be implemented. During mode of operation 506, capacitive element C6 may be incorporated in the output current path of pulser 400. As shown, during the mode of operation 506, transistors Q1, Q3, and Q7 may be turned off and transistors Q2, Q4, Q5, Q6 may be turned on. Thus, Iₒᵤₜ flows through capacitive element C6, transistors Q6, Q5, Q4, Q2, and capacitive element C2. As described, capacitive element C6 may be charged to 100 volts. Therefore, the mode of operation 506 implements the 100 volts at Uₒᵤₜ during the sheath collapse stage, as described with respect to FIG. 3A. In other words, Iₒᵤₜ flows in the opposite direction during mode of operation 506 (e.g., during the sheath collapse stage) as compared to modes of operation 502, 504 (e.g., during ion current stage), such that a positive voltage (e.g., 100 volts) is implemented during the sheath collapse stage and a negative voltage (e.g., between −1600 volts to −2400 volts) during the ion current stage.

FIG. 6 illustrates a charging circuit 600 used to charge a capacitive element 612, in accordance with certain aspects of the present disclosure. The capacitive element 612 may correspond to any one of capacitive elements 402, 404, 406, and 408. In other words, a charging circuit (e.g., similar to charging circuit 600) may be implemented for each of capacitive elements 402, 404, 406, and 408 to charge the capacitive elements to their respective voltages, as described herein. The charging circuit 600 may include an inverter 602 for converting a direct current (DC) voltage to an alternating current (AC) voltage. The AC voltage may be provided to a primary winding 606 of a transformer 604. The transformer may generate an AC voltage at the secondary winding 608 having a higher voltage than the AC voltage at the primary winding 606. For example, to charge capacitive element 402, the AC voltage at the secondary winding 608 may have a peak voltage of 800 volts. The AC voltage at the secondary winding 608 may be provided to a rectifier 610 to generate a DC signal used to charge the capacitive element 612.

FIG. 7 is a process flow diagram illustrating a method 700 of waveform generation, in accordance with certain embodiments of the present disclosure. The method 700 may be performed by a waveform generation system, including a waveform generator such as the pulser 400 and/or control circuitry such as the system controller 126.

At activity 702, the waveform generation system incorporates, during a first mode of operation (e.g., mode of operation 502), a first voltage source (e.g., capacitive element 402) in an output current path of a waveform generator (e.g., pulser 400) by controlling multiple switches. At activity 704, the waveform generation system incorporates, during a second mode of operation (e.g., mode of operation 504), a current source (e.g., inductive element 450 and capacitive element 406) in the output current path by controlling the multiple switches.

In some embodiments, the multiple switches include a first switch (e.g., transistor 410 or transistor 414) and a second switch (e.g., transistor 412 or transistor 416). A first terminal of the first voltage source (e.g., capacitive element 402 or capacitive element 404) is coupled to a first terminal of the first switch, and a second terminal of the first voltage source is coupled to a first terminal of the second switch. In some embodiments, the multiple switches also include a third switch (e.g., transistor 418) coupled in parallel with the current source. The third switch may be coupled to a common node between second terminals of the first switch and the second switch. In some embodiments, incorporating the first voltage source in the output current path may include closing the first switch, opening the second switch, and closing the third switch. Incorporating the current source in the output current path may include closing the first switch, opening the second switch, and opening the third switch.

In some embodiments, the waveform generation system incorporates, during the first mode of operation (e.g., mode of operation 502), a second voltage source (e.g., capacitive element 404) in the output current path by controlling the multiple switches. The multiple switches may further include a fourth switch (e.g., transistor 414) and a fifth switch (e.g., transistor 416). A first terminal of the second voltage source may be coupled to a first terminal of the fourth switch, a second terminal of the second voltage source may be coupled to a first terminal of the fifth switch, and a common node between second terminals of the fourth switch and the fifth switch may be coupled to the second switch (e.g., transistor 412) or the third switch (e.g., transistor 418). In some embodiments, incorporating the second voltage source in the output current path may include closing the fourth switch and opening the fifth switch.

In some embodiments, the waveform generation system may also incorporate, during a third mode of operation (e.g., mode of operation 506), a third voltage source (e.g., capacitive element 408) in the output current path by controlling the multiple switches. The multiple switches may include a sixth switch (e.g., transistor 420) and a seventh switch (e.g., transistor 422). A first terminal of the third voltage source may be coupled to a first terminal of the sixth switch, a second terminal of the third voltage source may be coupled to a first terminal of the seventh switch, and a common node between second terminals of the sixth switch and the seventh switch may be coupled to the third switch (e.g., transistor 418). In some embodiments, incorporating the third voltage source in the output current path may include closing the sixth switch and opening the seventh switch. The sixth switch may be open and the seventh switch may be closed during the first mode of operation and the second mode of operation. In some embodiments, a voltage associated with the first voltage source or the second voltage source (e.g., 600 volts) is greater than a voltage associated with the third voltage source (e.g., 100 volts).

The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A waveform generator, comprising:
a first voltage stage, comprising:
a first voltage source;
a first switch; and
a second switch, wherein:
a first terminal of the first voltage source is coupled to a first terminal of the first switch;
a second terminal of the first voltage source is coupled to a first terminal of the second switch and an output node of the waveform generator;
the second switch is disposed between a first node and the output node;
a second terminal of the first switch is coupled to the first node and a second terminal of the second switch; and
the output node is configured to be coupled to a load; and
a second voltage stage coupled between the first node and a ground node, wherein the first node is disposed between the second terminals of the first switch and the second switch, wherein the first voltage stage is connected with the output node, and wherein the second voltage stage is coupled to the output node through the first voltage stage.

2. The waveform generator of claim 1, wherein the first voltage source comprises a capacitive element.

3. The waveform generator of claim 1, wherein each of the first switch and the second switch comprise a transistor.

4. The waveform generator of claim 1, further comprising:
a current stage coupled to the second voltage stage, the current stage comprising:
a current source; and
a third switch coupled to the current source, wherein the current source is coupled in parallel with the third switch.

5. The waveform generator of claim 4, wherein the current source comprises:
a capacitive element; and
an inductive element coupled in series with the capacitive element.

6. The waveform generator of claim 4, further comprising a diode coupled between a first terminal and a second terminal of the third switch.

7. The waveform generator of claim 6, wherein the diode comprises a body diode of the first switch.

8. The waveform generator of claim 1, wherein:
the first voltage source comprises a first capacitive element; and
the waveform generator further comprises one or more charging circuits configured to charge the first capacitive element.

9. The waveform generator of claim 8, wherein the second voltage stage comprises:
a second voltage source;
a third switch; and
a fourth switch, wherein:
a first terminal of the second voltage source is coupled to a first terminal of the third switch;
a second terminal of the second voltage source is coupled to a first terminal of the fourth switch and the first node;
the fourth switch is disposed between a second node and the first node; and
the second node is coupled to the ground node, a second terminal of the third switch, and a second terminal of the fourth switch.

10. The waveform generator of claim 1, wherein the load comprises a plasma formed in a processing chamber.

11. A waveform generator, comprising:
a first voltage stage, comprising:
a first voltage source;
a first switch; and
a second switch, wherein:
a first terminal of the first voltage source is coupled to a first terminal of the first switch;
a second terminal of the first voltage source is coupled to a first terminal of the second switch and an output node of the waveform generator;
the second switch is disposed between a first node and the second terminal of the first voltage source, wherein the first terminal of the second switch and the second terminal of the first voltage source are connected with the output node;
a second terminal of the first switch is coupled to the first node and a second terminal of the second switch; and
the output node is configured to be coupled to a load;
a second voltage stage coupled between the first node and a ground node, wherein the first node is disposed between the second terminals of the first switch and the second switch; and
a current stage coupled between the second voltage stage and the ground node.

12. The waveform generator of claim 11, wherein the first voltage source comprises a capacitive element.

13. The waveform generator of claim 11, wherein each of the first switch and the second switch comprise a transistor.

14. The waveform generator of claim 11, wherein the current stage comprises:
a current source; and
a third switch coupled to the current source, wherein the current source is coupled in parallel with the third switch.

15. The waveform generator of claim 14, wherein the current source comprises:
a capacitive element; and
an inductive element coupled in series with the capacitive element.

16. The waveform generator of claim 15, further comprising a diode coupled between a first terminal and a second terminal of the third switch.

17. The waveform generator of claim 16, wherein the diode comprises a body diode of the third switch.

18. The waveform generator of claim 11, wherein:
the first voltage source comprises a first capacitive element; and
the waveform generator further comprises one or more charging circuits configured to charge the first capacitive element.

19. The waveform generator of claim 11, wherein the second voltage stage comprises:
a second voltage source;
a third switch; and
a fourth switch, wherein:
a first terminal of the second voltage source is coupled to a first terminal of the third switch;
a second terminal of the second voltage source is coupled to a first terminal of the fourth switch and the first node;
the fourth switch is disposed between a second node and the first node; and
the second node is coupled to the ground node, a second terminal of the third switch, and a second terminal of the fourth switch.

20. The waveform generator of claim 11, wherein the load comprises a plasma formed in a processing chamber.
